(19) United States
(12) Patent Application Publication
(10) Pub. No.: US 2018/0062002 A1
(43) Pub. Date: Mar. 1, 2018

(54) SOLAR CELL

(71) Applicant: NEO SOLAR POWER CORP., Hsinchu City (TW)

(72) Inventors: Wei-Hao CHIU, Hsinchu City (TW); Je-Wei LIN, Hsinchu City (TW); Wei-Ming CHEN, Hsinchu City (TW); Chie-Sheng LIU, Hsinchu City (TW); Shan-Chuang PEI, Hsinchu City (TW); Wei-Chih HSU, Hsinchu City (TW)

(73) Assignee: NEO SOLAR POWER CORP., Hsinchu City (TW)

(21) Appl. No.: 15/657,662

(22) Filed: Jul. 24, 2017

(30) Foreign Application Priority Data
Aug. 24, 2016 (TW) 105212907

(51) Int. Cl. H01L 31/02; H01L 31/0224; H01L 31/072

(52) U.S. Cl. CPC H01L 31/0201; H01L 31/072; H01L 31/022425

(57) ABSTRACT

A solar cell includes a semiconductor substrate, one or more bus bar electrode, and a plurality of finger electrodes. The bus bar electrode and the finger electrodes are disposed on the semiconductor substrate. Conventionally, in a process of forming the finger electrodes by utilizing screen printing, offset may occur. Consequently, the finger electrodes cannot be connected to the bus bar electrode. According to the provided solar cell, the bus bar electrode is formed by using patterned silver and aluminum, to manufacture a wider bus bar electrode than the bus bar electrode in the conventional solar cell without increasing silver consumption, thereby resolving the problem of offset.

### CROSS-REFERENCE TO RELATED APPLICATION

This non-provisional application claims priority under 35 U.S.C. §119(a) to Patent Application No. 105212907 filed in Taiwan, R.O.C. on Aug. 24, 2016, the entire contents of which are hereby incorporated by reference.

### BACKGROUND

### Technical Field

The present invention relates to a solar cell.

### Related Art

With the shortage of global energy and increasing serious environmental pollution, development of green energy that can also consider environmental protection becomes a very important topic.

Solar cells are one of products of the green energy topic. The solar cells can convert radiation energy of sunlight to electricity, and no hazardous substance causing environmental pollution is generated in the process of the energy conversion. Based on the feature, the solar cells are widely used in each field gradually.

However, a main structural configuration of a solar cell is a plurality of bus bar electrodes and a plurality of finger electrodes that are formed on a silicon substrate by utilizing a manner of screen printing. The finger electrodes are mainly configured to collect currents generated from photo-electric effect and transfer the currents to the bus bar electrodes, and then the bus bar electrodes transfers the currents collected by the finger electrodes to an external power storage apparatus or powered apparatus.

Generally, configuration of bus bar electrodes 12 and finger electrodes 13 on a silicon substrate 11 of a solar cell 10 is shown in FIG. 1. The bus bar electrodes 12 on the silicon substrate 11 extend from one side of the silicon substrate 11 to the other side along a first direction D1, and the bus bar electrodes 12 are disposed parallel to each other. However, the finger electrodes 13 are distributed in spaces between the bus bar electrodes 12, and each of the finger electrodes 13 is configured orthogonally to the bus bar electrodes 12. Because each of the finger electrodes 13 is configured orthogonally to the bus bar electrodes 12, and the finger electrodes 13 are configured as a fine line width with consideration of sunlight shielding rate, only smallest parts of ends of the finger electrodes 13 are connected to the bus bar electrodes 12. Therefore, when offset occurs in a process of forming the finger electrodes 13 by utilizing screen printing, as shown in FIG. 2, a contact area of the end of the finger electrode 13 with a left side of the bus bar electrode 12 is different from that of the end of the finger electrode 13 with a right side of the bus bar electrode 12. Consequently, a resistance of the left side is different from that of the right side, resulting in reduction of conversion efficiency of the solar cell 10. If the offset is more serious, as shown in FIG. 3, one side of the finger electrodes 13 are not connected to the bus bar electrodes 12, resulting in more significant reduction of the conversion efficiency of the solar cell 10.

In addition, because it is considered that the bus bar electrodes 12 need to be highly conductive, the bus bar electrodes 12 are made of silver paste having excellent electrical conductivity. In a common configuration, a width of the bus bar electrode 12 is configured as several times of the width of the finger electrode 13. Therefore, a ratio of a cost of the silver paste accounting for a cost of the whole solar cell 10 is still high. However, if the width of the bus bar electrode 12 is increased to avoid offset, consumption and a cost of silver paste will be significantly increased.

### SUMMARY

The present invention provides a solar cell, to improve the problem of offset that easily occurs during manufacturing of the foregoing finger electrode and the bus bar electrode.

The solar cell includes a semiconductor substrate, at least one bus bar electrode group, and a plurality of finger electrodes. The at least one bus bar electrode group is disposed on the semiconductor substrate, and extends by a length along a first direction. The at least one bus bar electrode group includes a main bus bar electrode and an auxiliary bus bar electrode. The main bus bar electrode includes a plurality of main bus bar electrode units, where the main bus bar electrode units are disposed at intervals along the first direction, and each of the main bus bar electrode units extends by a length along the first direction and has a first width on a second direction. The auxiliary bus bar electrode includes a plurality of first auxiliary bus bar electrode units and a plurality of second auxiliary bus bar electrode units, where at least one end of each of the first auxiliary bus bar electrode units along the first direction is connected to one of the second auxiliary bus bar electrode units, each of the first auxiliary bus bar electrode units has a second width on the second direction, and second width is greater than the first width. Each of the second auxiliary bus bar electrode units individually corresponds to each of the main bus bar electrode units, and each of the second auxiliary bus bar electrode units locally covers the corresponding main bus bar electrode unit. The plurality of finger electrodes are disposed on the semiconductor substrate, where each of the finger electrodes extends by a length along the second direction, and is connected to at least one of the first auxiliary bus bar electrode unit or the second auxiliary bus bar electrode unit.

In addition, the solar cell may also have another configuration. The solar cell includes a semiconductor substrate, at least one bus bar electrode group, and a plurality of finger electrodes. The at least one bus bar electrode group is disposed on the semiconductor substrate, where each of the at least one bus bar electrode group extends by a length along a first direction, and includes a main bus bar electrode and an auxiliary bus bar electrode. The main bus bar electrode extends by a length along the first direction and has a first width on a second direction. The auxiliary bus bar electrode corresponds to the main bus bar electrode, and locally covers two side edges that are along the second direction and that are of a top surface of the corresponding main bus bar electrode. The plurality of finger electrodes is disposed on the semiconductor substrate, where each of the finger electrodes extends by a length along the second direction, and is connected to the auxiliary bus bar electrode.

According to a design of the bus bar electrode group, the main bus bar electrode may be made of silver, and the auxiliary bus bar electrode may be made of aluminum. As long as the length or the width of the main bus bar electrode is reduced, and the reduced part is replaced with aluminum, the width of the bus bar electrode group is increased without increasing consumption of silver, thereby reducing a probability of offset.

### BRIEF DESCRIPTION OF THE DRAWINGS

FIG. 1 is a schematic diagram of a known solar cell;

FIG. 2 is schematic diagram I of translation offset of a finger electrode in a known solar cell;

FIG. 3 is schematic diagram II of translation offset of a finger electrode in a known solar cell;

FIG. 4 is a schematic top view of a solar cell according to an embodiment of the present invention;

FIG. 5 is a schematic top view of a solar cell according to another embodiment of the present invention;

FIG. 6 is a schematic top view of a solar cell according to still another embodiment of the present invention;

FIG. 7 is a structural diagram of a unit of a solar cell according to an embodiment of the present invention;

FIG. 8-1 is a cross section chart along a section line 3-3 in FIG. 7;

FIG. 8-2 is a cross section chart along a section line 4-4 in FIG. 7;

FIG. 9-1 is a cross section chart along a section line 5-5 in FIG. 7;

FIG. 9-2 is a cross section chart along a section line 6-6 in FIG. 7;

FIG. 10 is a schematic diagram of a position of a notch of a solar cell according to an embodiment of the present invention;

FIG. 11 is a cross section chart along a section line 7-7 in FIG. 10;

FIG. 12 is a schematic diagram of a position of a notch of a solar cell according to another embodiment of the present invention;

FIG. 13 is a cross section chart along a section line 8-8 in FIG. 12;

FIG. 14-1 is another cross section chart along a section line 3-3 in FIG. 7;

FIG. 14-2 is another cross section chart along a section line 4-4 in FIG. 7;

FIG. 15-1 is another cross section chart along a section line 5-5 in FIG. 7;

FIG. 15-2 is another cross section chart along a section line 6-6 in FIG. 7;

FIG. 16 is another structural diagram of a unit of a solar cell according to an embodiment of the present invention;

FIG. 17 is a schematic top view of a solar cell according to yet another embodiment of the present invention;

FIG. 18 is a locally enlarged schematic diagram of a solar cell according to yet another embodiment of the present invention;

FIG. 19 is a cross section chart along a section line 10-10 in FIG. 18;

FIG. 20 is a cross section chart along a section line 11-11 in FIG. 18; and

FIG. 21 is a schematic diagram of a solar cell module consisting of several solar cells.

### DETAILED DESCRIPTION

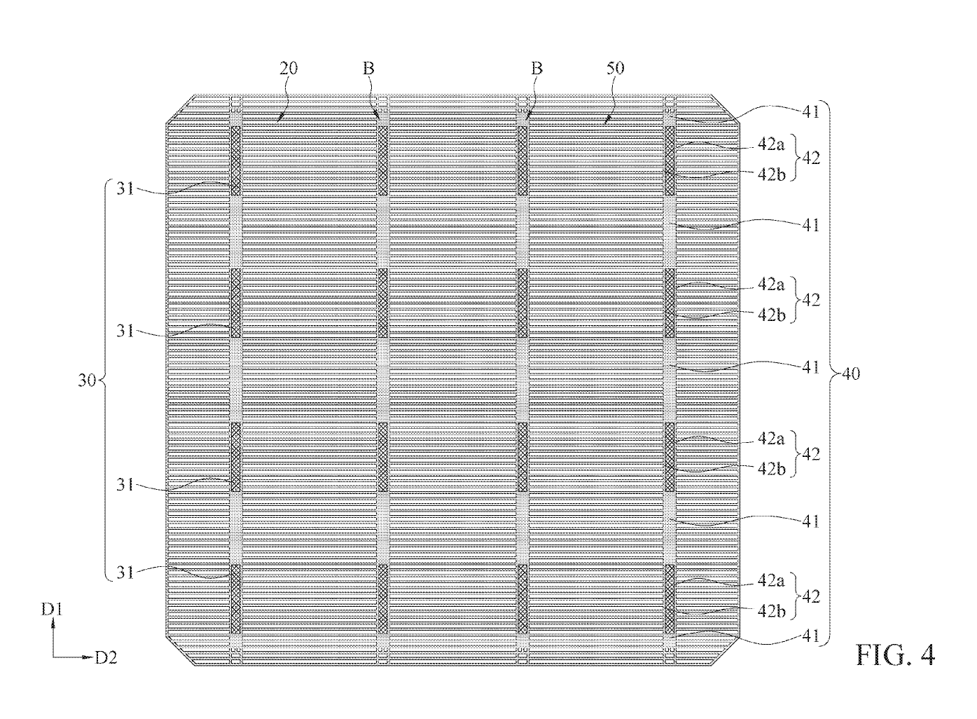

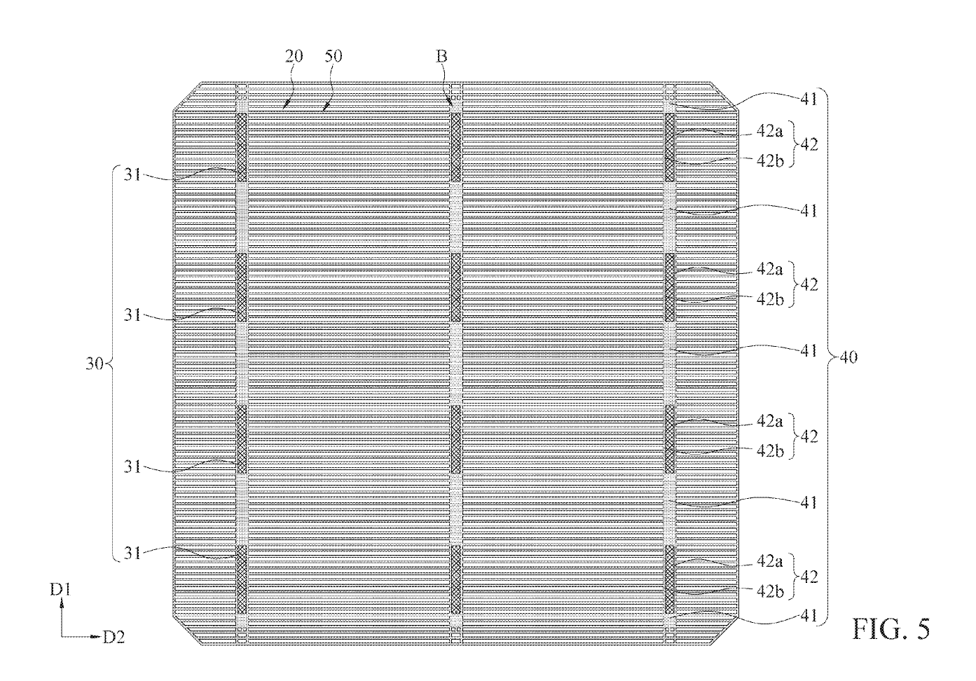

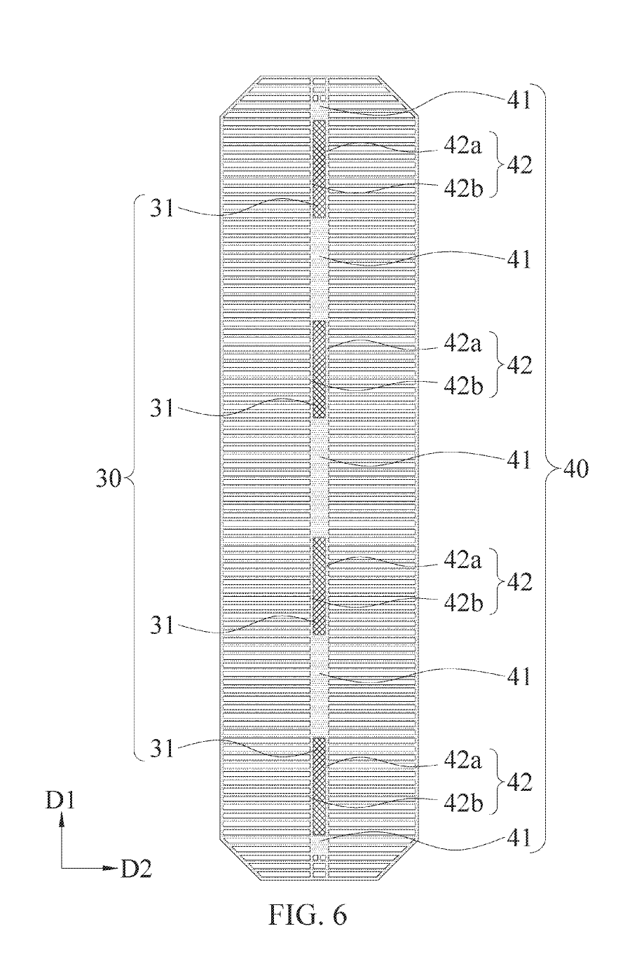

Referring to FIG. 4, FIG. 5, and each of FIG. 6, FIG. 4, FIG. 5, and FIG. 6 shows a configuration of a solar cell including four bus bar electrode groups B, three bus bar electrode groups B, and a bus bar electrode group B respectively. A solar cell of the present invention includes a semiconductor substrate 20, at least one bus bar electrode group B, and a plurality of finger electrodes 50, where each of the at least one bus bar electrode group B includes a main bus bar electrode 30 and an auxiliary bus bar electrode 40 respectively. The bus bar electrode group B extends by a length along a first direction D1, and a direction that is perpendicular to the first direction D1 is defined as a second direction D2. When there are multiple bus bar electrode groups B as shown in FIG. 4 and FIG. 5, each of the bus bar electrode groups B are disposed parallel to each other along the second direction D2 at intervals on the semiconductor substrate 20. The following embodiments respectively describe various configurations of a bus bar electrode group B and a connection relationship with a finger electrode of the bus bar electrode group B.

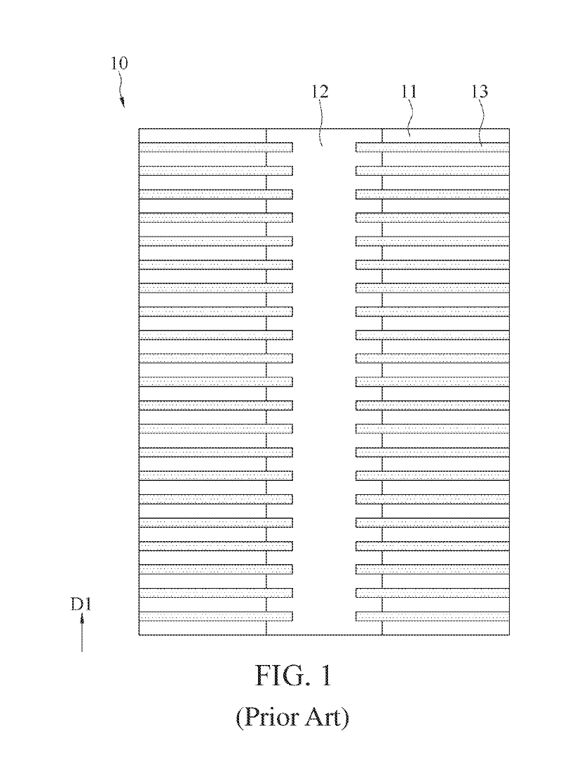

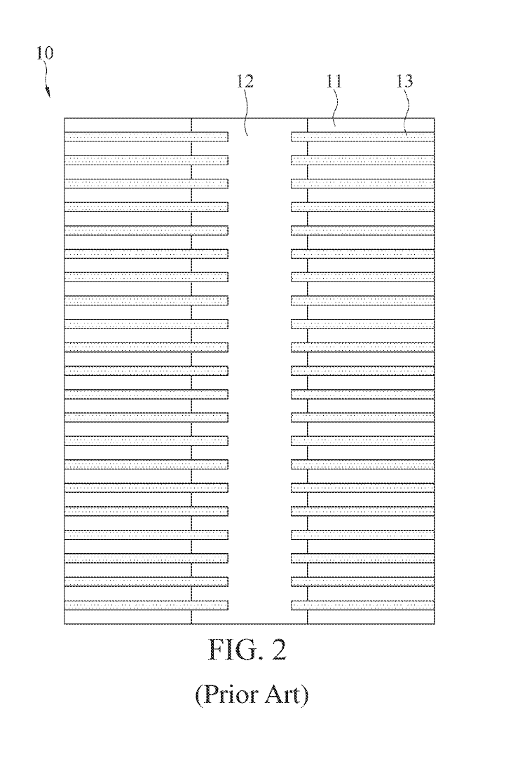

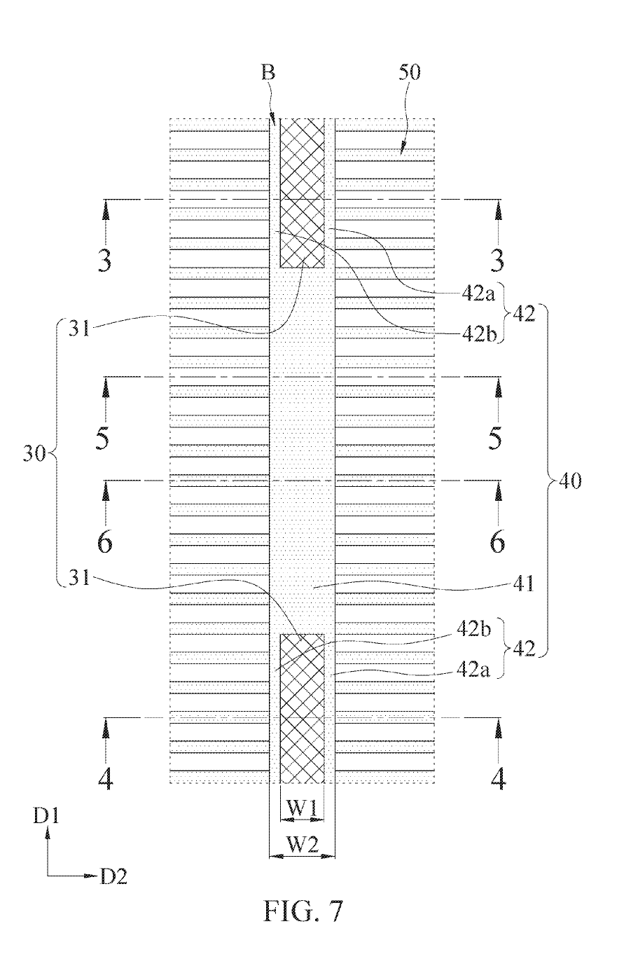

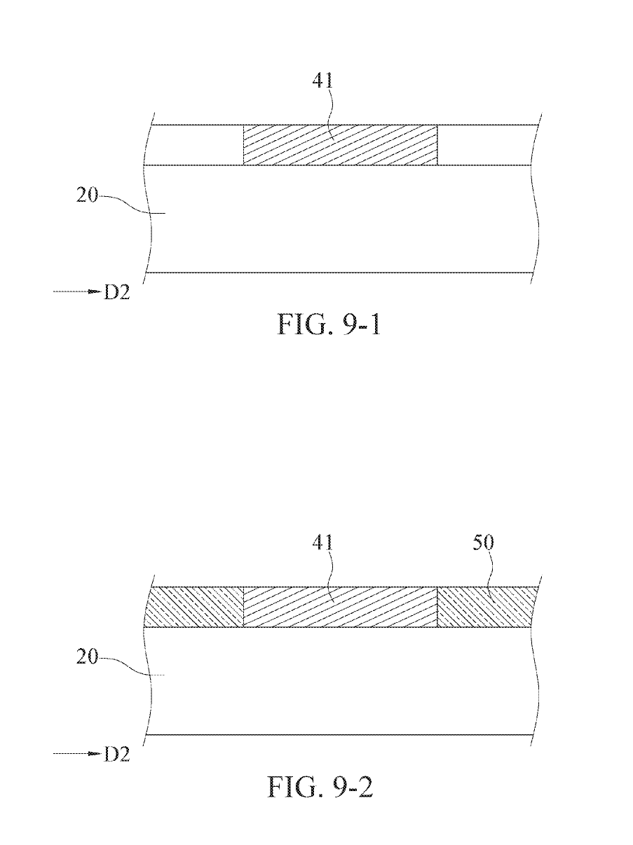

Further referring to FIG. 7 to FIG. 9-2, FIG. 7 to FIG. 9-2 are respectively a structural diagram of a unit of a solar cell according to an embodiment of the present invention, a cross section chart along a section line 3-3 in FIG. 7, and a cross section chart along a section line 5-5 in FIG. 7. In this embodiment, a main bus bar electrode 30 includes main bus bar electrode units 31. A quantity of the main bus bar electrode units 31 included in each main bus bar electrode 30 is at least 2. Four main bus bar electrodes 30 are shown in the figures, but the present invention is not limited thereto. The main bus bar electrode units 31 extends by a length along a first direction D1 and are disposed on the first direction D1 at intervals, and have a first width W1 on a second direction D2. The main bus bar electrode units 31 of this embodiment may be formed by using silver paste sintering. As shown in FIG. 8-1 and FIG. 8-2, each of the main bus bar electrode units 31 respectively has a bottom surface 311 connected to a semiconductor substrate 20, a top surface 312 opposite to the bottom surface 311, and a side surface 313 connecting the top surface 312 and the bottom surface 311.

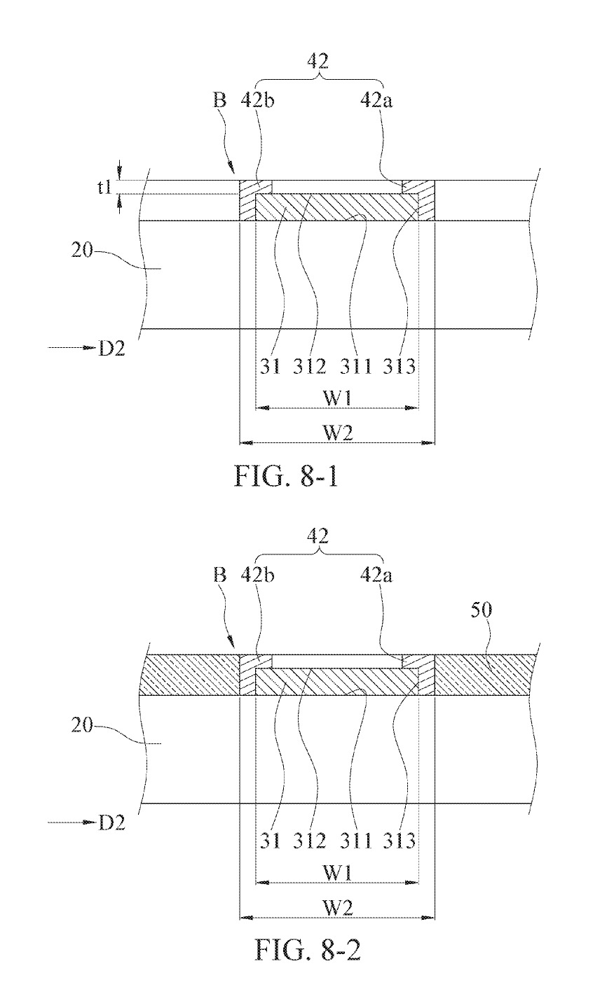

An auxiliary bus bar electrode 40 of this embodiment may be formed by using aluminum paste sintering. As shown in FIG. 7, FIG. 8-1, and FIG. 8-2, the auxiliary bus bar electrode 40 includes first auxiliary bus bar electrode units 41 and second auxiliary bus bar electrode units 42. Each auxiliary bus bar electrode 40 includes at least one first auxiliary bus bar electrode unit 41 and two second auxiliary bus bar electrode units 42, and a quantity of the second auxiliary bus bar electrode units 42 is the same as that of the main bus bar electrode units 31.

At least one end of each of the first auxiliary bus bar electrode units along the first direction D1 is connected to one of the second auxiliary bus bar electrode units 42, each of the first auxiliary bus bar electrode units 41 has a second width W2 on the second direction, and the second width W2 is greater than the first width W1. Each of the second auxiliary bus bar electrode units 42 individually corresponds to each of the main bus bar electrode units 31, and each of the second auxiliary bus bar electrode units 42 locally covers the corresponding main bus bar electrode unit 31. That is, at least a part of surface of the main bus bar electrode unit 31 is still naked and is not covered by the second auxiliary bus bar electrode unit 42. A width of the whole auxiliary bus bar electrode 40 along the second direction D2 is equal to the width W2 of a first auxiliary bus bar electrode unit 41 along the second direction D2, and W2 ranges from 0.1 mm to 3.0 mm.

Referring to FIG. 4, FIG. 5, and FIG. 7, the first auxiliary bus bar electrode units 41 and the second auxiliary bus bar electrode units 42 of the auxiliary bus bar electrode 40 are staggered at intervals on the first direction D1. The main bus bar electrode units 31 of each of the bus bar electrode groups B correspond to the second auxiliary bus bar electrode units 42, therefore, the main bus bar electrode units 31 and the first auxiliary bus bar electrode units 41 are staggered at intervals on the first direction D1. End-to-end connection is applied between the main bus bar electrode units 31 and the first auxiliary bus bar electrode units 41 on the first direction D1, and end-to-end connection is also applied between the second auxiliary bus bar electrode units 42 and the first auxiliary bus bar electrode units 41 on the first direction D1.

As shown in FIG. 7, FIG. 8-1, and FIG. 8-2, if a length direction of the second auxiliary bus bar electrode unit 42 is a symmetric axis, the second auxiliary bus bar electrode unit 42 may be divided into two left-right halves 42a and 42b. Each half of the second auxiliary bus bar electrode unit 42a or 42b extends from the top surface 312 of the main bus bar electrode unit 31 to the side surface 313, and further extends to the semiconductor substrate 20. In an embodiment, a width of an edge of a top surface 312 of a main bus bar electrode unit 31 covered by a second auxiliary bus bar electrode unit 42 ranges from 75 μm to 1,550 μm, a corresponding covered area is about 2.9% to 60.3% of a total area of the top surface 312, and a side surface 313 is completely covered by the second auxiliary bus bar electrode unit 42. In an embodiment, an area of a top surface 312 of a main bus bar electrode unit 31 covered by a second auxiliary bus bar electrode unit 42 approximately accounts for 3.8% to 40.9% of a total area of the top surface 312.

Finger electrodes 50 and the bus bar electrode groups B are disposed on a same side of the semiconductor substrate 20, and the finger electrodes 50 may be formed by using aluminum paste sintering. Each of the finger electrodes 50 extends by a length along the second direction D2, is placed parallel to each other at intervals between the bus bar electrode groups B, and is connected to each of the auxiliary bus bar electrodes 40. That is, one end of each of the finger electrodes 50 is connected to at least one of the first auxiliary bus bar electrode unit 41 or the second auxiliary bus bar electrode unit 42, but is not directly connected to the main bus bar electrode unit 31. In this embodiment, a width of the finger electrode 50 along the first direction D1 is defined as W3. In addition, in some solar cells (for example, conventional Passivated Emitter and Rear Cell), before rear finger electrodes are formed on a rear face of a semiconductor substrate, multiple openings (hereinafter referred to as laser openings) are first formed by using laser melting, then silver paste or aluminum paste is filled in the laser openings in a manner of screen painting, and finally heat treatment, sintering, is performed to form the rear finger electrodes. Refer to Patent documents, ROC Publication Nos. M526758, I542022, and I535039 for a formation mode of a laser opening and a purpose of forming a laser opening, and details are not described herein again. In an embodiment, because an auxiliary bus bar electrode 40 is connected to one end of a finger electrode 50, on a projection direction of the semiconductor substrate 20, a bottom of the auxiliary bus bar electrode 40 can cover the laser openings. In another embodiment, laser openings are even formed directly under an auxiliary bus bar electrode 40, and the auxiliary bus bar electrode 40 is formed on the laser openings.

The above describes structural configurations and features of embodiments of the present invention. When the solar cell is used, each of the finger electrodes 50 is used to collect a current generated from photo-electric effect, and carriers collected by each of the finger electrodes 50 are conducted to the bus bar electrode groups B for collection, and then are output for storage or use.

According to the embodiments of the present invention, because a bus bar electrode group B that is used to output collected currents includes a main bus bar electrode 30 made of silver and an auxiliary bus bar electrode 40 made of aluminum, compared with a structure of bus bar electrodes that are made of only silver paste, under a same area of a solar cell, a same quantity of bus bar electrodes, and same consumption of silver paste, a width of the bus bar electrode group B in the embodiments of the present invention on the second direction D2 may be designed wider.

In addition, from an aspect of manufacturing screen painting, according to the embodiments of the present invention, a material of the main bus bar electrode 30 is different from that of the auxiliary bus bar electrode 40 and that of the finger electrodes 50 respectively. Therefore, in a manufacture procedure of the present invention embodiment, the main bus bar electrode 30 must be first manufactured, and the auxiliary bus bar electrode 40 and the finger electrodes 50 are manufactured. The auxiliary bus bar electrode 40 and the finger electrodes 50 may be manufactured in a same manufacture procedure of screen printing. Alternatively, the bus bar electrodes 40 may be first screen-printed, and the finger electrodes 50 are screen-printed. The finger electrode 50 of the embodiments of the present invention is connected to one of the first auxiliary bus bar electrode unit 41 or the second auxiliary bus bar electrode unit 42 of the auxiliary bus bar electrode 40, and an extension direction of the second auxiliary bus bar electrode unit 42 is perpendicular and orthogonal to the finger electrode 50. That is, because the bus bar electrode group B of the embodiments of the present invention includes the main bus bar electrode 30 that is specially designed and the auxiliary bus bar electrode 40, the second width W2 of the auxiliary bus bar electrode 40 along the second direction D2 may be designed wider than a width of a conventional bus bar electrode, so that the finger electrode 50 is still connected to the first auxiliary bus bar electrode unit 41 or the second auxiliary bus bar electrode unit 42 even if translation offset misalignment occurs in a process of screen printing, to effectively solve a problem that an end of the finger electrode 50 is easily separated from the bus bar electrode once translation offset occurs in a process of manufacturing the conventional solar cell. It is seen that, by using an ingenious design of the bus bar electrode group B, a production line of the solar cell can have a relatively high fault-tolerant capability for translation offset in the manufacture procedure.

In addition, quantities of first auxiliary bus bar electrode units 41, second auxiliary bus bar electrode units 42, and main bus bar electrode units 31 in each bus bar electrode group B are shown in FIG. 4. Four bus bar electrode groups B may be configured, each of the bus bar electrode groups B includes four main bus bar electrode units 31, five first auxiliary bus bar electrode units 41, and four second auxiliary bus bar electrode units 42. As shown in FIG. 5, three bus bar electrode groups B may be configured, and each of the bus bar electrode groups B also includes four main bus bar electrode units 31, five first auxiliary bus bar electrode units 41, and four second auxiliary bus bar electrode units 42. As further shown in FIG. 6, only bus bar electrode group B may be configured, and the bus bar electrode groups B also includes four main bus bar electrode units 31, five first auxiliary bus bar electrode units 41, and four second auxiliary bus bar electrode units 42. It is noted herein that the quantities of the first auxiliary bus bar electrode units 41, the second auxiliary bus bar electrode units 42, and the main bus bar electrode units 31 are only examples. The present invention is not limited to the configurations. For example, the quantity of the main bus bar electrode units 31 may also be 2 or 3, or even be 5 or more; the quantity of the first auxiliary bus bar electrode units 41 may also correspond to the quantity of the main bus bar electrode units 31, and may be 3, 4 or at least 6; and similarly, the quantity of the second auxiliary bus bar electrode units 42 may also correspond to the quantity of the main bus bar electrode units 31, and may be 2, 3, or at least 5.

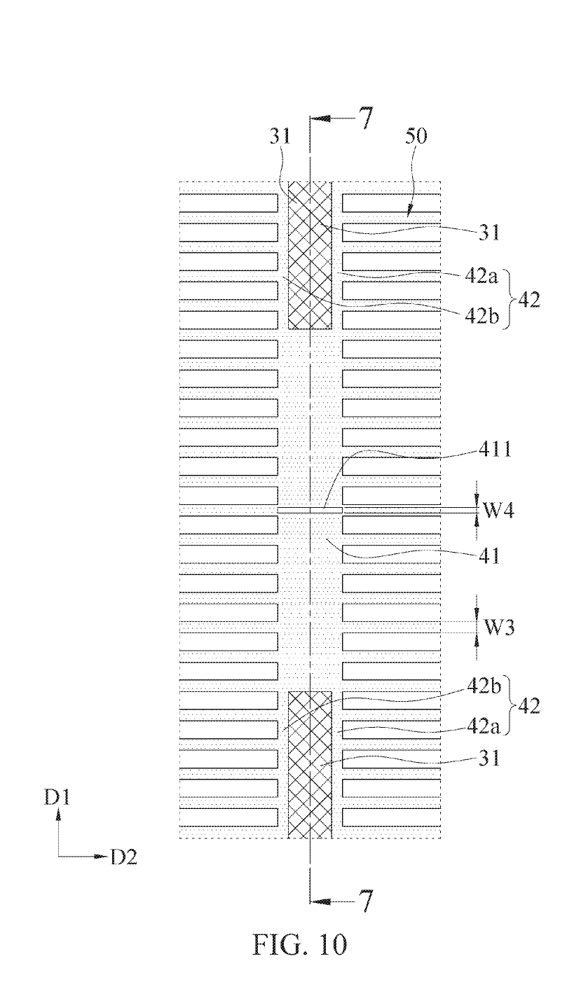

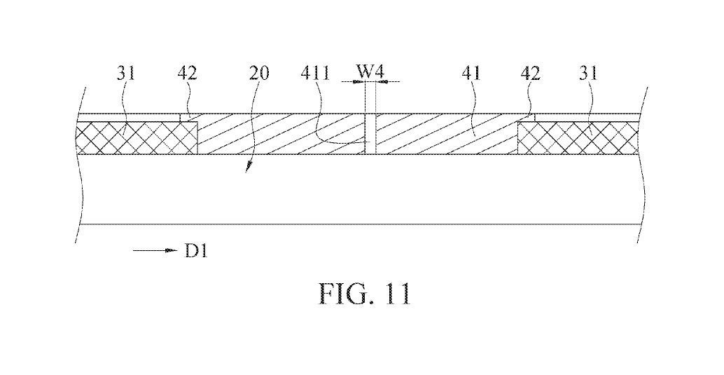

In addition, still another embodiment of the present invention is further shown in FIG. 10 and FIG. 11, a notch 411 is disposed on a first auxiliary bus bar electrode unit 41 of this embodiment. The notch 411 extends by a length along a second direction D2, and the length of the notch 411 along the second direction D2 is equal to or greater than a second width W2 of the first auxiliary bus bar electrode unit 41. Because a depth of the notch 411 is equal to a thickness of the first auxiliary bus bar electrode unit 41, the first auxiliary bus bar electrode unit 41 is divided into two halves. Two ends of the notch 411 along the second direction D2 are separately connected to an end face of the finger electrode 50, and the notch 411 has a fourth width W4 on a first direction D1, where the fourth width W4 is less than a third width W3 of the finger electrode 50 on the first direction D1. It should be noted that, if the fourth width W4 of the notch 411 is greater than or equal to the third width W3 of the finger electrode 50 on the first direction D1, efficiency of a solar cell is caused to significantly reduce.

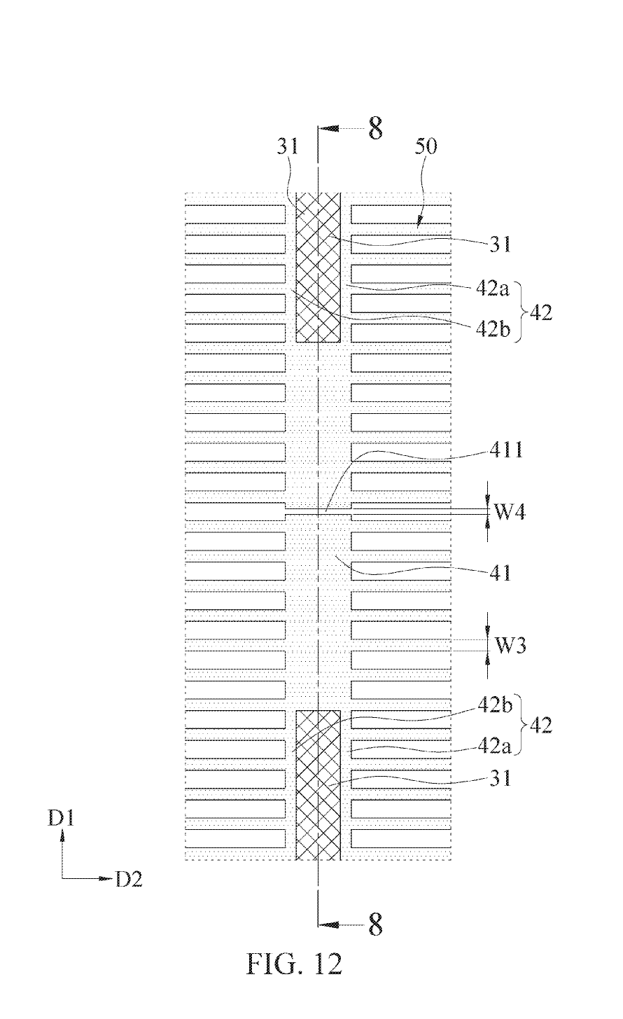

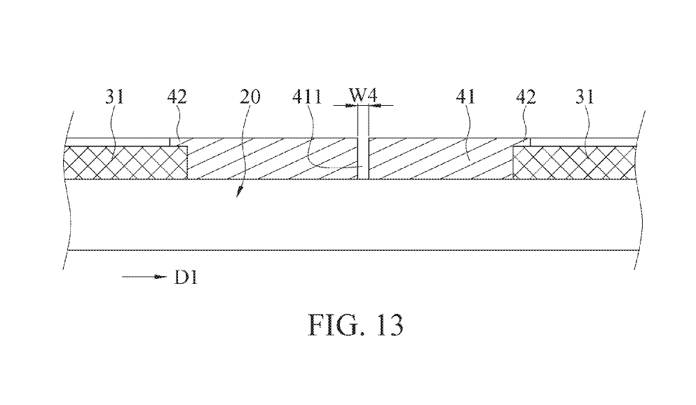

Still another embodiment of the present invention is shown in FIG. 12 and FIG. 13. Compared with the configuration shown in FIG. 10 and FIG. 11, in this embodiment, two ends of a notch 411 along a second direction D2 are separately connected to intervals between two neighboring finger electrodes 50, and a width W4 of the notch 411 on a first direction D1 is less than or equal to a third width W3 of the finger electrode 50 on the first direction D1. It should be noted that, if the fourth width W4 of the notch 411 is greater than the third width W3 of the finger electrode 50 on the first direction D1, efficiency of a solar cell is caused to significantly reduce.

According to the solar cell in the embodiments, a thickness t1 of a part of the second auxiliary bus bar electrode unit 42 covering the corresponding main bus bar electrode unit 31 ranges from 10 μm to 50 μm. Specially, when t1 is between 15 μm and 30 μm, the efficiency of the solar cell is the best. If the thickness t1 of the part of the second auxiliary bus bar electrode unit 42 covering the corresponding main bus bar electrode unit 31 is excessive, for example, greater than 50 μm, consequently, when formed solar cells are welded and connected in series by using a welding strip, welding between the welding strip and the main bus bar electrode unit 31 can easily become faulty.

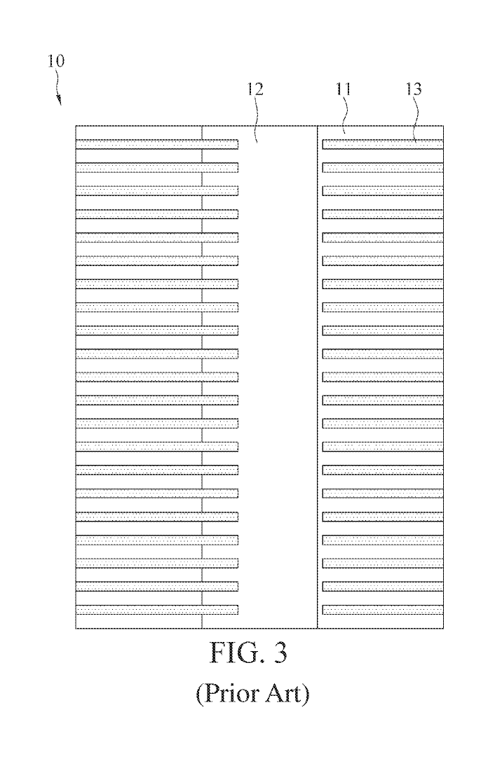

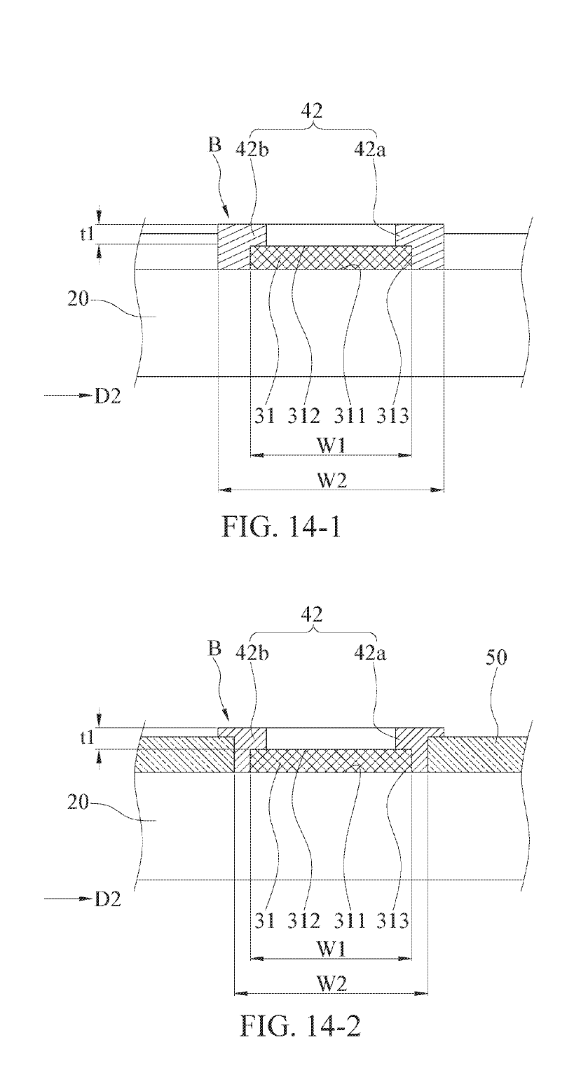

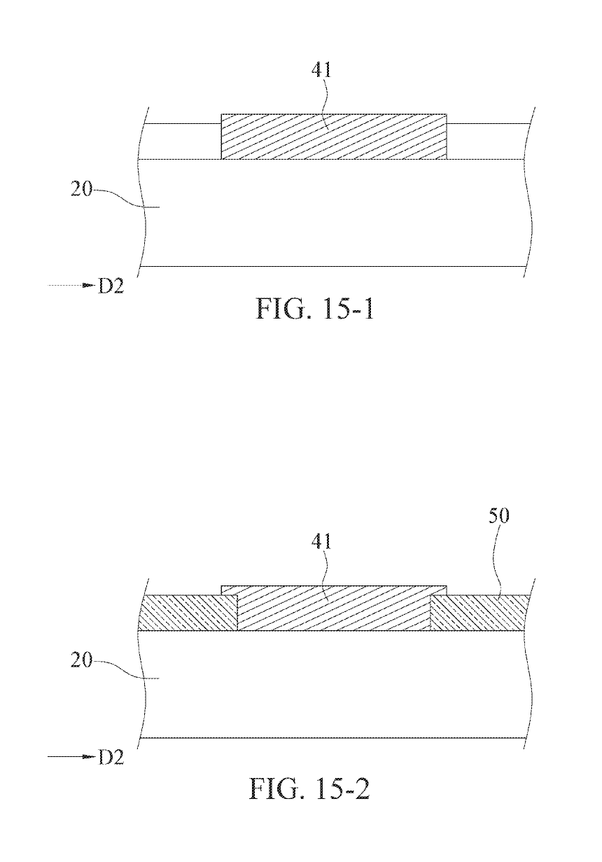

Further referring to FIG. 14-1 to FIG. 15-2, the figures show another configuration of the solar cell shown in FIG. 8-1 to FIG. 9-2, and a difference between the two configurations is that, in this embodiment, a first auxiliary bus bar electrode unit 41 and a second auxiliary bus bar electrode unit 42 locally cover a finger electrode 50 that is connected to the first auxiliary bus bar electrode unit 41 and the second auxiliary bus bar electrode unit 42. As shown in FIG. 14-2, FIG. 14-2 is another cross section chart along a section line 4-4 in FIG. 7. FIG. 14-2 shows that the second auxiliary bus bar electrode unit 42 locally covers the finger electrode 50 that is connected to the second auxiliary bus bar electrode unit 42. As further shown in FIG. 15-2, FIG. 15-2 is another cross section chart along a section line 6-6 in FIG. 7. FIG. 15-2 shows that the first auxiliary bus bar electrode unit 41 locally covers the finger electrode 50 that is connected to the first auxiliary bus bar electrode unit 41.

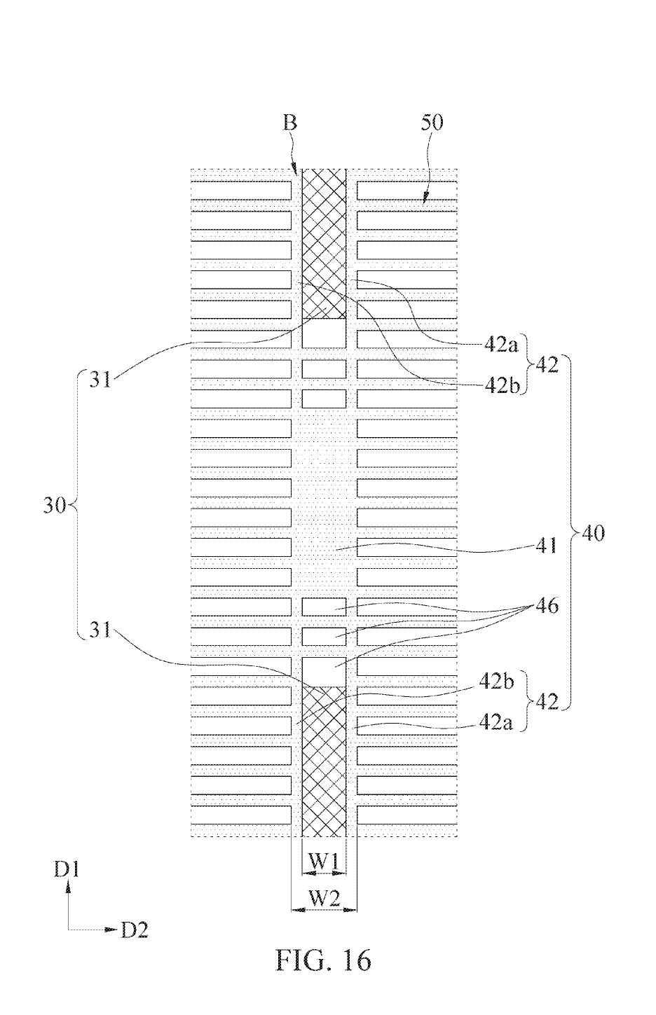

Further referring to FIG. 16, FIG. 16 is another structural diagram of a unit of a solar cell according to an embodiment of the present invention. A difference between the structural diagram of a unit and the structural diagram of a unit of the solar cell shown in FIG. 7 is that a first auxiliary bus bar electrode unit 41 further includes at least one hollow region 46, where the hollow region 46 is close to a main bus bar electrode unit 31. Existence of the hollow region 46 may reduce material consumption of the first auxiliary bus bar electrode unit 41, thereby reducing a manufacturing cost of the whole solar cell, and may avoid a problem of low welding yield resulted from a height difference between the first auxiliary bus bar electrode unit 41 and the main bus bar electrode unit 31.

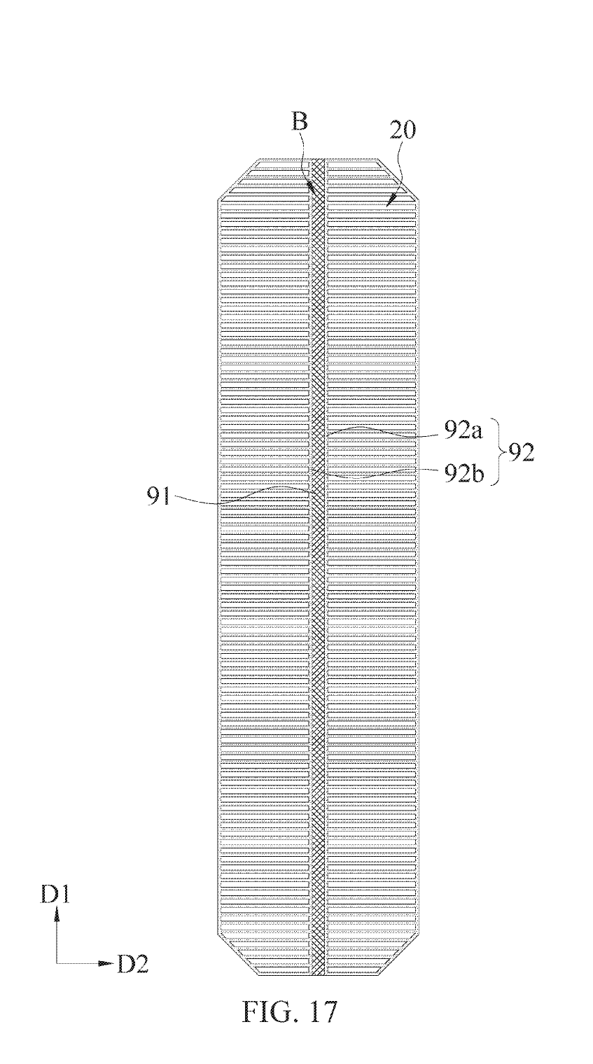

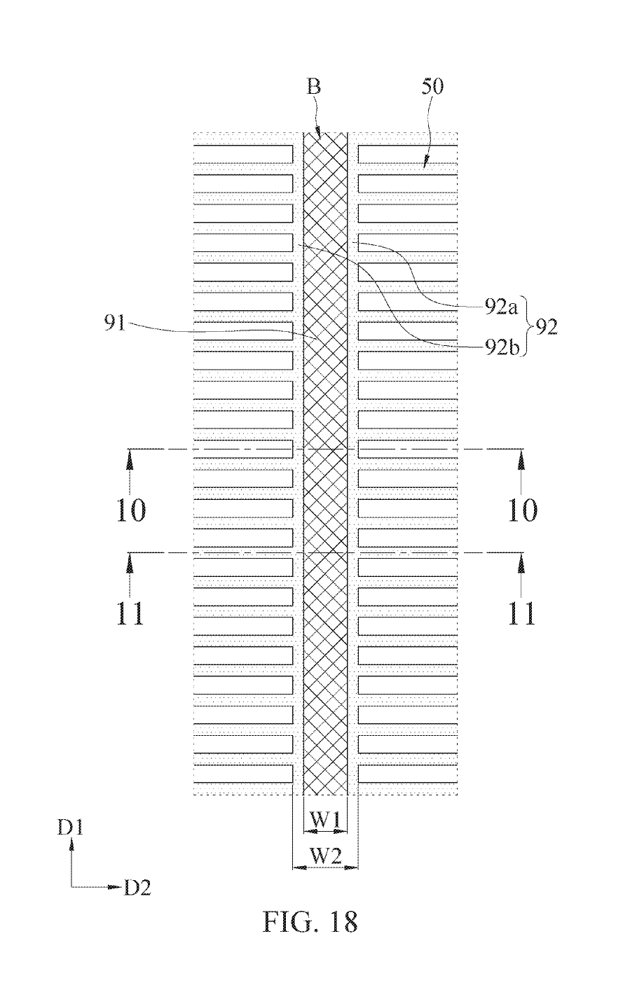

Further referring to FIG. 17 to FIG. 20, FIG. 17 to FIG. 20 show a solar cell according to yet another embodiment of the present invention. A difference between the solar cell and the foregoing solar cell is that, in this embodiment, a main bus bar electrode is not in island shaped, but a continuous-line. According to this embodiment, the solar cell also includes a semiconductor substrate 20, a bus bar electrode group B, and a plurality of finger electrodes 50. FIG. 17 only shows one bus bar electrode group B, but the figure is merely for convenience of description. This embodiment also may be applied to a solar cell including multiple bus bar electrode groups B.

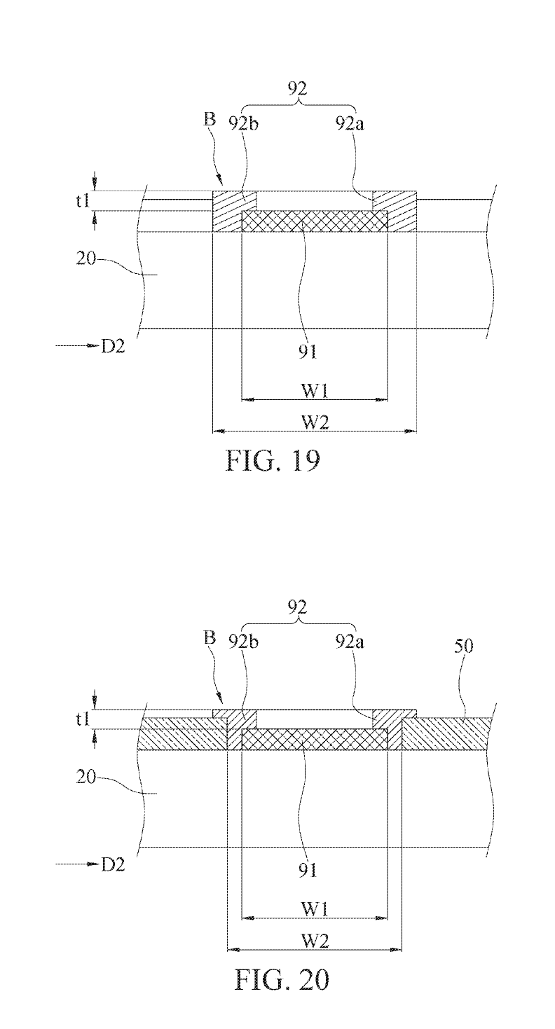

The bus bar electrode group B is disposed on the semiconductor substrate 20, extends by a length along a first direction D1, and includes a main bus bar electrode 91 and an auxiliary bus bar electrode 92. The main bus bar electrode 91 extends by a length along the first direction D1, and has a first width W1 on a second direction D2. The auxiliary bus bar electrode 92 is disposed correspondingly to the main bus bar electrode 91, and locally covers two side edges that are along the second direction D2 and that are of a top surface of the corresponding main bus bar electrode 91. Moreover, a width of the auxiliary bus bar electrode 92 along the second direction D2 ranges from 0.1 mm to 3.0 mm. The finger electrodes 50 are disposed on the semiconductor substrate 20, and each of the finger electrodes 50 extends by a length along the second direction D2 and is connected to the auxiliary bus bar electrode 92. The auxiliary bus bar electrode 92 may be divided into two left-right halves 92a and 92b. As shown in FIG. 19 and FIG. 20, the left half auxiliary bus bar electrode 92a locally covers the main bus bar electrode 91, and also locally covers the finger electrodes 50 that are connected to 92a. Similarly, the right half auxiliary bus bar electrode 92b locally covers the main bus bar electrode 91, and also locally covers the finger electrodes 50 that are connected to 92b. In addition, in some solar cells (for example, conventional Passivated Emitter and Rear Cell), before rear finger electrodes are formed on a rear face of a semiconductor substrate, multiple openings (hereinafter referred to as laser openings) are first formed by using laser melting, then silver paste or aluminum paste is filled in the laser openings in a manner of screen painting, and finally heat treatment, sintering, is performed to form the rear finger electrodes. Refer to Patent documents, ROC Publication Nos. M526758, I542022, and I535039 for a formation mode of a laser opening and a purpose of forming a laser opening, and details are not described herein again. In an embodiment, because an auxiliary bus bar electrode 92 is connected to one end of a finger electrode 50, on a projection direction of the semiconductor substrate 20, a bottom of the auxiliary bus bar electrode 92 can cover the laser openings. In another embodiment, laser openings are even formed directly under an auxiliary bus bar electrode 92, and the auxiliary bus bar electrode 92 is formed on the laser openings.

The embodiments may be appropriate for any solar cell whose both sides can generate electricity, especially for but not limited to a Passivated Emitter Rear Cell (PERC for short) solar cell and so on. For the PERC solar cell, a front emitter and a rear side are passivated by using a passivation technology, to reduce a probability of recombination of electrons and electron holes on a surface of a semiconductor substrate, thereby have higher conversion efficiency than that of a common solar cell whose rear side is not passivated.

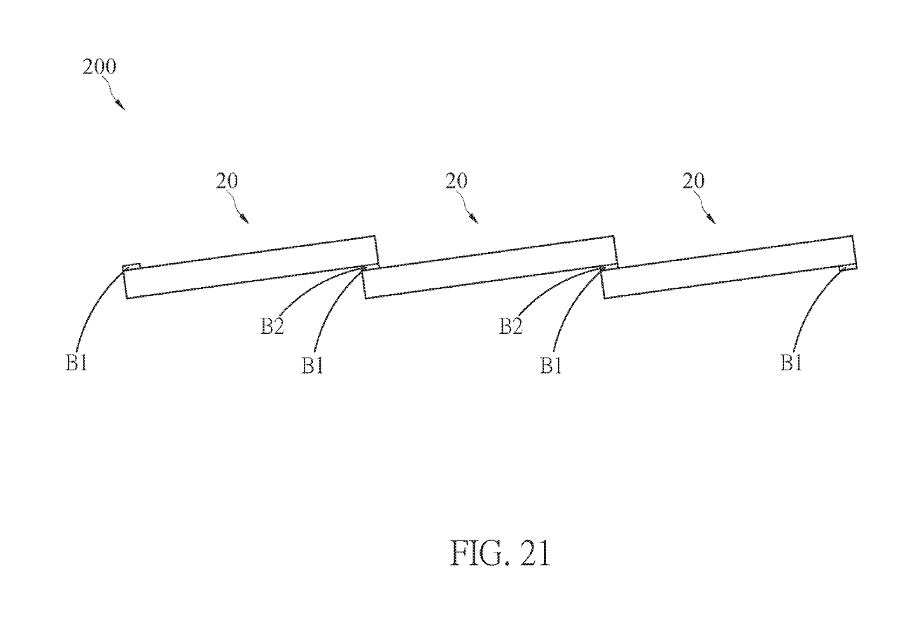

The solar cell according to the present invention could be applied to a heterojunction solar cell or applied to a solar cell module which consists of several overlapping solar cells. Referring to FIG. 21, a solar cell module 200 consisting of several solar cells 20 is illustrated. Each solar cell 20 includes a bus bar electrode group B1 and a bus bar electrode group B2. The bus bar electrode group B1 is disposed at one surface of the solar cell 20, while the bus bar electrode group B2 is disposed at the other surface of the solar cell 20. Therefore, the bar electrode group B2 of solar cell 20 could be connected to the bar electrode group B1 of its neighboring solar cell 20 in a way of series connection. Of course, the bar electrode group B1 of solar cell 20 could be connected to the bar electrode group B1 of its neighboring solar cell 20 in a way of parallel connection as well.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A solar cell, comprising:
a semiconductor substrate;
at least one bus bar electrode group, disposed on the semiconductor substrate, wherein each of the at least one bus bar electrode group extends by a length along a first direction, and the at least one bus bar electrode group comprises:
a main bus bar electrode, comprising a plurality of main bus bar electrode units, wherein the main bus bar electrode units are disposed at intervals along the first direction, and each of the main bus bar electrode units extends by a length along the first direction and has a first width on a second direction that is perpendicular to the first direction; and
an auxiliary bus bar electrode, comprising a plurality of first auxiliary bus bar electrode units and a plurality of second auxiliary bus bar electrode units, wherein at least one end of each of the first auxiliary bus bar electrode units is connected to one of the second auxiliary bus bar electrode units along the first direction, each of the first auxiliary bus bar electrode units has a second width on the second direction, and the second width is greater than the first width; and each of the second auxiliary bus bar electrode units individually corresponds to each of the main bus bar electrode units, and each of the second auxiliary bus bar electrode units locally covers the corresponding main bus bar electrode unit; and
a plurality of finger electrodes, disposed on the semiconductor substrate, wherein each of the finger electrodes extends by a length along the second direction, and is connected to at least one of the first auxiliary bus bar electrode unit or the second auxiliary bus bar electrode unit.

2. The solar cell according to claim 1, wherein each of the main bus bar electrode unit has a bottom surface connected to the semiconductor substrate, a top surface opposite to the bottom surface, and a side surface connecting the top surface and the bottom surface, each of the second auxiliary bus bar electrode units locally covers the top surface of the corresponding main bus bar electrode unit and completely covers the side surface of the main bus bar electrode unit.

3. The solar cell according to claim 2, wherein the second auxiliary bus bar electrode unit locally covers a periphery on the top surface of the corresponding main bus bar electrode unit, and an area of the periphery is 2.9% to 60.3% of an area of the top surface.

4. The solar cell according to claim 2, wherein the second auxiliary bus bar electrode unit locally covers a periphery on the top surface of the corresponding main bus bar electrode unit, and an area of the periphery is 3.8% to 40.9% of an area of the top surface.

5. The solar cell according to claim 1, wherein the first auxiliary bus bar electrode unit has a notch, the notch extends by a length along the second direction, a length of the notch along the second direction is equal to the second width of the first auxiliary bus bar electrode unit, and a width of the notch on the first direction is less than or equal to the width of each of the finger electrodes along the first direction.

6. The solar cell according to claim 5, wherein the notch is disposed in an interval between two neighboring finger electrodes.

7. The solar cell according to claim 5, wherein each of two ends of the notch along the second direction is separately connected to one of the finger electrodes.

8. The solar cell according to claim 1, wherein a material of the main bus bar electrode is silver, and a material of the auxiliary bus bar electrode and the finger electrodes is aluminum.

9. The solar cell according to claim 1, wherein a thickness of a part of the second auxiliary bus bar electrode unit covering the corresponding main bus bar electrode unit ranges from 10 μm to 50 μm.

10. The solar cell according to claim 9, wherein the thickness of the part of the second auxiliary bus bar electrode unit covering the corresponding main bus bar electrode unit ranges from 15 μm to 30 μm.

11. The solar cell according to claim 10, wherein the first auxiliary bus bar electrode unit locally covers the finger electrodes that are connected to the first auxiliary bus bar electrode, and the second auxiliary bus bar electrode unit locally covers the finger electrodes that are connected to the second auxiliary bus bar electrode unit.

12. The solar cell according to claim 1, wherein a width of the auxiliary bus bar electrode along the second direction ranges from 0.1 mm to 3.0 mm.

13. The solar cell according to claim 1, wherein the semiconductor substrate has an opening that is formed by using laser, and the auxiliary bus bar electrode is formed on the opening.

14. The solar cell according to claim 1, wherein the first auxiliary bus bar electrode has at least one hollow region, and the at least one hollow region is adjacent to the main bus bar electrode unit.

15. The solar cell according to claim 1, wherein the solar cell is selected from a heterojunction solar cell and a solar cell consists of several overlapping solar cell units.

16. A solar cell, comprising:
a semiconductor substrate;
at least one bus bar electrode group, disposed on the semiconductor substrate, wherein each of the at least one bus bar electrode group extends by a length along a first direction, and the at least one bus bar electrode group comprises:
a main bus bar electrode, wherein the main bus bar electrode extends by a length along the first direction and has a first width on a second direction that is perpendicular to the first direction; and
an auxiliary bus bar electrode, wherein the auxiliary bus bar electrode corresponds to the main bus bar electrode, and locally covers two side edges that are along the second direction and that are of a top surface of the corresponding main bus bar electrode; and
a plurality of finger electrodes, disposed on the semiconductor substrate, wherein each of the finger electrodes extends by a length along the second direction, and is connected to the auxiliary bus bar electrode.

17. The solar cell according to claim 16, wherein a thickness of a part of the auxiliary bus bar electrode covering the corresponding main bus bar electrode ranges from 10 μm from 50 μm.

18. The solar cell according to claim 17, wherein the thickness of the part of the auxiliary bus bar electrode covering the corresponding main bus bar electrode ranges from 15 μm to 30 μm.

19. The solar cell according to claim 16, wherein a width of the auxiliary bus bar electrode along the second direction ranges from 0.1 mm to 3.0 mm.

20. The solar cell according to claim 16, wherein the semiconductor substrate has an opening that is formed by using laser, and the auxiliary bus bar electrode is formed on the opening.

21. The solar cell according to claim 16, wherein the solar cell is a heterojunction solar cell or a solar cell consists of several overlapping solar cell units.
